(19) United States
(12) Patent Application Publication
(10) Pub. No.: US 2025/0385207 A1
(43) Pub. Date: Dec. 18, 2025

(54) SEMICONDUCTOR DEVICE, MOUNTING SUBSTRATE, AND ELECTRONIC DEVICE

(71) Applicant: SONY SEMICONDUCTOR SOLUTIONS CORPORATION, KANAGAWA (JP)

(72) Inventor: KAZUTOSHI YOKOYAMA, KUMAMOTO (JP)

(21) Appl. No.: 18/878,899

(22) PCT Filed: Jun. 30, 2023
(86) PCT No.: PCT/JP2023/024326

§ 371 Date: Dec. 25, 2024

(30) Foreign Application Priority Data
Jul. 13, 2022 (JP) 2022-112654

(51) Int. Cl. H01L 23/00

(52) U.S. Cl. CPC H01L 24/13; H01L 24/11; H01L 24/14; H01L 24/16; H01L 2224/1132; H01L 2224/13014; H01L 2224/13017; H01L 2224/13019; H01L 2224/13144; H01L 2224/13155; H01L 2224/14131; H01L 2224/16227; H01L 2924/35121

(57) ABSTRACT

Provided are a semiconductor device in which stress applied to a column connecting a semiconductor package and a wiring board is relaxed, a mounting substrate having the semiconductor device, and an electronic device having the semiconductor device and the mounting substrate. A semiconductor device according to the present disclosure includes a semiconductor package having a plurality of lands on a lower surface, a column having a flange portion at least at an upper end and joined to one of the lands, and a first solder portion joining the land and the flange portion of the column, in which the first solder portion has a melting point equivalent to a melting point of a second solder portion joining a lower end of the column to a land of a wiring board, and the column is joined to the land of the semiconductor package via the first solder portion. Furthermore, the mounting substrate according to the present disclosure is configured so that the lower end of the column of the semiconductor device is joined to the wiring board by the second solder portion. Furthermore, an electronic device including the semiconductor device or the mounting substrate is configured.

### TECHNICAL FIELD

The present disclosure relates to a semiconductor device, a mounting substrate including the semiconductor device, and an electronic device including the semiconductor device and the mounting substrate.

### BACKGROUND ART

Conventionally, with the progress of miniaturization of a semiconductor process and increase in speed of semiconductor elements, high integration of semiconductor elements has progressed. In accordance with the progress of high integration of semiconductor elements, the number of external connection terminals of semiconductor elements is rapidly increasing. For this reason, structures of various semiconductor packages capable of arranging a large number of terminals while suppressing an increase in size of the semiconductor package have appeared.

As a structure of a semiconductor package compatible with multi-terminal semiconductor devices, a surface mount type package structure in which a large number of external connection terminals are arranged on a bottom surface of the package and soldering is performed on a wiring board has appeared. As a surface mount package structure, for example, a pin grid array (PGA), a ball grid array (BGA, hereinafter referred to as “BGA”), a land grid array (LGA, hereinafter referred to as “LGA”), a column grid array (CGA), and the like are known.

In the surface mount type package structure, since the connection terminals are arranged on the bottom surface of the package without protruding around the package, the semiconductor device can be downsized, and the mounting density can be increased. Furthermore, since the connection terminals can be arranged with high density, it is possible to meet the needs for multi-terminals. Moreover, since connection terminal lengths are short, the inductance can be reduced, and there is an advantage that the connection terminals are suitable for a package of a semiconductor device that is driven at a high speed.

However, since the surface mount type package structure cannot be soldered by hand, it is necessary to perform soldering using a reflow furnace. Further, once soldering is performed, since the state of soldering cannot be visually confirmed, a special device is required to inspect the state of soldering, and it is difficult to repair in a case where there is a soldering defect. Furthermore, there is also a disadvantage that it is necessary to reheat the wiring board at the time of removal, and repair may not be possible depending on the heat-resistant temperature of the components of the package.

Moreover, with the increase in density, terminals and the like to be soldered are miniaturized, and mechanical strength tends to decrease. Furthermore, since the linear expansion coefficient of the package is different from the linear expansion coefficient of the wiring board to be mounted, thermal expansion and thermal contraction are repeated due to heat generation due to energization and a temperature change of a use environment. The stress generated by this may cause cracks in the soldered portion.

Patent Document 1 discloses a semiconductor device in which a plurality of internal terminals and a plurality of external terminals are formed on a wiring board, each internal terminal and each external terminal are electrically connected to each other, a semiconductor pellet fixed to the wiring board is electrically connected to each internal terminal, and each pin (terminal) is mechanically and electrically connected to each external terminal, in which each pin is set to have an outer diameter of 0.03 mm to 0.1 mm and a length of 0.5 mm to 1.2 mm.

With such a configuration, since the outer diameter of the pins is thin, the pitch between the pins can be narrowed, the mounting density can be increased by area arrangement of the pins, and the pins can be surface-mounted by abutting the wiring board against lands. Then, in this manner, the distance between the semiconductor device and the wiring board can be maintained, and thus, for example, inter-pin short failure due to crushing of a solder bump in the case of BGA can be prevented.

Patent Document 2 discloses a package for housing a semiconductor element, the package including a base constituted by ceramics and having, on an upper surface thereof, a mounting portion on which a semiconductor element is mounted and an electrode to which a semiconductor element formed on the mounting portion is electrically connected, a lower surface electrode formed on a lower surface of the base and electrically connected to the electrode via a through conductor, and a substantially cylindrical connection terminal having one end joined to the lower surface electrode via a brazing material and having a height of 0.2 to 0.5 mm, a cross-sectional diameter of 0.15 to 0.5 mm, and a Vickers hardness of 20 to 50 Hv, in which the brazing material has a contact angle of 45° or less with respect to a surface of the connection terminal when melted.

In addition, there is disclosed a semiconductor device including the package for housing a semiconductor element described above and a semiconductor element mounted and fixed on the mounting portion and electrically connected to the electrode.

Specifically, in the semiconductor device having the above configuration, the diameter of the cross section of the connection terminal is 0.15 to 0.5 mm, which is larger than that in the conventional case, and thus, even if no flange portion is formed, the area of the end surface of the connection terminal in contact with the bottom electrode increases, and the bonding strength can be made sufficient. Furthermore, since the height of the connection terminal is as low as 0.2 to 0.5 mm, resistance force against external force in a horizontal direction increases. Moreover, by setting the Vickers hardness of the connection terminal to 20 to 50 Hv, stress generated between the semiconductor package and an external electric circuit device due to heat of the semiconductor element can be effectively alleviated by deflection.

### CITATION LIST

### Patent Document

Patent Document 1: Japanese Patent Application Laid-Open No. H10-261735
Patent Document 2: Japanese Patent Application Laid-Open No. 2003-249598

### SUMMARY OF THE INVENTION

### Problems to be Solved by the Invention

Here, the pins (terminals) of the semiconductor device described in Patent Document 1 have a flange portion on a joint surface with the package, and is soldered to a soldering portion disposed on the lower surface of the wiring board with a high melting point solder material (hereinafter referred to as “high-temperature solder”). However, some of the pins soldered by the high-temperature solder are not a little inclined or have variations in height. In this state, the semiconductor device is soldered to the wiring board with a low melting point solder material (hereinafter referred to as “low-temperature solder”). When the pin is soldered in an inclined state, the solder of a soldered portion soldered by the high-temperature solder does not melt, so that the soldered portion on the wiring board side is pulled toward the wiring board side by surface tension of the melted low-temperature solder, and solidified while tensile stress is applied. Furthermore, in a case where the soldering height by the high-temperature solder is uneven, the pin having a high height is pressed with the tip of the pin abutting on the wiring board, and the solder solidified while compressive stress is applied.

Moreover, the outer diameter of the pin is 0.03 mm to 0.1 mm, and is extremely small in view of the fact that the average diameter of European and American hair is 0.05 mm and the diameter of Japanese hair is 0.08 mm. Therefore, damage and bending of the pin easily occur during soldering and it is necessary to pay careful attention to handling of the pin, and thus there is a problem that workability is poor. Then, when the pin is soldered to the wiring board by low-temperature solder in a state of being slightly inclined, bent, or pressed against the wiring board, the solder solidifies while stress is applied.

Since it solidifies in a state in which stress is applied in this manner, residual stress is generated in the pin. When used in a state where residual stress is present, tensile stress and compressive stress generated by a difference in linear expansion coefficient in thermal fluctuation are further applied, so that weakening of fatigue strength, corrosion cracking, embrittlement, or the like may occur, and peeling of a soldered portion or occurrence of cracks may occur.

However, it is not assumed that a residual stress may be originally generated in the pin of the semiconductor device described in Patent Document 1. Moreover, since the bonding area of soldering is small, the structure has a weak soldering strength in the first place. Therefore, there is a problem that peeling or cracking of a soldered portion occurs due to tensile stress or compressive stress generated by thermal fluctuation in addition to residual stress.

A connection terminal (pin) of the semiconductor device described in Patent Document 2 is connected to a lower electrode disposed on a lower surface of a substrate constituted of ceramic by brazing. This connection terminal is also soldered to the wiring board by low-temperature solder as in the invention described in Patent Document 1. However, when the external terminal is soldered in an inclined state, the brazed lower electrode-side solder is not melted, and thus the soldered portion on the wiring board side is pulled toward the wiring board side by the surface tension of the melted low-temperature solder. Furthermore, in a case where the brazing height is high, the connection terminal is pressed against the wiring board. Therefore, the low-temperature solder solidifies while the connection terminal is deflected (plastically deformed) by tensile stress or compressive stress.

When such a stress is applied and used in a state in which deflection (plastic deformation) is generated, the stress generated by the difference in linear expansion coefficient in the thermal fluctuation is further applied, and thus the deformation amount may increase beyond the allowable limit of deflection (plastic deformation).

However, it is not originally assumed that stress is applied to the connection terminal of the semiconductor device described in Patent Document 2 by soldering by low-temperature solder. Moreover, in the first place, the generation of the deflection (plastic deformation) itself is not preferable because it is no longer possible to return to the original shape.

The present disclosure has been made in view of such problems, and an object of the present disclosure is to provide a semiconductor device in which stress applied to a connection terminal (hereinafter referred to as a “column”) connecting a package of the semiconductor device and a wiring board is relaxed, a mounting substrate having the semiconductor device, and an electronic device having the semiconductor device and the mounting substrate.

### Solutions to Problems

The present disclosure has been made to solve the above-described problems, and a first aspect thereof is a semiconductor device including:
a semiconductor package having a plurality of lands on a lower surface;
a column having a flange portion at least at an upper end and joined to one of the lands; and
a first solder portion joining the land and the flange portion of the column, in which
the first solder portion has a melting point equivalent to a melting point of a second solder portion joining a lower end of the column to a land of a wiring board, and
the column is joined to the land of the semiconductor package via the first solder portion.

Furthermore, in the first aspect, the column may have a second flange portion at the lower end.

Furthermore, in the first aspect, the flange portion may be covered with the first solder portion, and a portion having a pedestal thickness of the flange portion exists on a straight line connecting an upper end peripheral edge and a rising height h1 of the first solder portion.

Further, in the first aspect, a configuration may be employed in which each of the lands of the semiconductor package, the column having the flange portion at least at an upper end, the first solder portion, the second solder portion, and the land of the wiring board
satisfy a relationship of 3D/2≤R≤2D,
satisfy a relationship of 3d≤r≤4d, and
satisfy a relationship of L≥1+H, where
a diameter of the land of the semiconductor package is R,
a diameter of the flange portion at an upper end of the column is D,
a total length of the column is L,
a diameter of a body portion of the column is d,
a diameter of the land of the wiring board to which the lower end of the column is joined is r,
a rising height of the first solder portion from an upper end of the flange portion is h1,
a rising height of the second solder portion from a lower end of the body portion is h2, and
a bending margin of the column is l, and
H is a constant satisfying H=h1+h2.

Further, in the first aspect, a configuration may be employed in which
each of the lands of the semiconductor package, the column having the flange portion at an upper end and the second flange portion at a lower end, the first solder portion, the second solder portion, and the land of the wiring board
satisfy a relationship of 3D/2≤R≤2D,
satisfy a relationship of 3D_{L}/2≤r≤2D_{L}, and
satisfy a relationship of L≥1+H, where
a diameter of the land of the semiconductor package is R,
a diameter of the flange portion at an upper end of the column is D,
a diameter of the second flange portion at a lower end of the column is D_{L},
a total length of the column is L,
a diameter of the land of the wiring board to which the second flange portion at the lower end of the column is joined is r,
a rising height of the first solder portion from an upper end of the flange portion is h1,
a rising height of the second solder portion from a lower end of the body portion is h2, and
a bending margin of the column is l, and
H is a constant satisfying H=h1+h2.

Furthermore, in the first aspect, the value of the constant H may be 0.48 when the column is plated with nickel gold (NiAu).

Further, in the first aspect, in the column, a solder suction band may be formed at least in a region of a rising height h2 of the second solder portion.

Furthermore, in the first aspect, the solder suction band may be plated with nickel gold (NiAu).

Furthermore, in the first aspect, the solder suction band may have a plurality of grooves formed along an axial direction in a peripheral side surface of the column.

Furthermore, in the first aspect, the solder suction band may have a slot passing through an axis of the column.

Furthermore, in the first aspect, the solder suction band may have a cross groove passing through an axis of the column.

Furthermore, in the first aspect, the first solder portion and the second solder portion may be low-temperature solders having equivalent melting points.

Furthermore, a second aspect of the present invention is a mounting substrate including:
a semiconductor device including:
a semiconductor package having a plurality of lands on a lower surface;
a column having a flange portion at least at an upper end and joined to one of the lands; and
a first solder portion joining the land and the flange portion of the column, in which
the first solder portion has a melting point equivalent to a melting point of a second solder portion joining a lower end of the column to a land of a wiring board, and
the column is joined to the land of the semiconductor package via the first solder portion, and the semiconductor device is joined to the land of the wiring board via the column and the second solder portion.

Furthermore, a third aspect of the present invention is an electronic device including:
a semiconductor device including
a semiconductor package having a plurality of lands on a lower surface,
a column having a flange portion at least at an upper end and joined to one of the lands, and
a first solder portion joining the land and the flange portion of the column, in which
the first solder portion has a melting point equivalent to a melting point of a second solder portion joining a lower end of the column to a land of a wiring board, and
the column is joined to the land of the semiconductor package via the first solder portion; or
a mounting substrate including a semiconductor device in which the column is joined to the land of the semiconductor package via the first solder portion is joined to the land of the wiring board via the column and the second solder portion.

By adopting the above aspect, it is possible to provide a semiconductor device in which stress applied to a column connecting a package of the semiconductor device and a wiring board is relaxed, a mounting substrate having the semiconductor device, and an electronic device having the semiconductor device and the mounting substrate.

### BRIEF DESCRIPTION OF DRAWINGS

FIG. 1 is a side view and a bottom view illustrating an example of column arrangement of a semiconductor device according to the present disclosure.

FIG. 2 is a front view and a bottom view illustrating a column of the semiconductor device of a first embodiment according to the present disclosure.

FIG. 3 is an X1-X1 line sectional end view illustrating a soldered state of the column in FIG. 2.

FIG. 4 is a graph of actual measurement data of a 1% cumulative failure rate according to a column size of a column having no flange portion.

FIG. 5 is a graph of actual measurement data of a 1% cumulative failure rate according to a column size of a column having a flange portion of the semiconductor device according to the present disclosure.

FIG. 6 is an explanatory view illustrating a difference in a soldered state depending on a pedestal thickness of a flange portion of the column in FIG. 3.

FIG. 7 is an explanatory view of a soldering step of the column of the semiconductor device of the first embodiment according to the present disclosure (part 1).

FIG. 8 is an explanatory view of a soldering step of the column of the semiconductor device of the first embodiment according to the present disclosure (part 2).

FIG. 9 is an explanatory view of a soldering step of the column of the semiconductor device of the first embodiment according to the present disclosure (part 3).

FIG. 10 is an explanatory view of a state in which the semiconductor device of the first embodiment according to the present disclosure is soldered to a wiring board.

FIG. 11 is a front view and a bottom view illustrating a column of a semiconductor device of a second embodiment according to the present disclosure.

FIG. 12 is a front view and a bottom view illustrating a column of a semiconductor device of a third embodiment according to the present disclosure.

FIG. 13 is a front view and a bottom view illustrating a column of a semiconductor device of a fourth embodiment according to the present disclosure.

FIG. 14 is a front view and a bottom view illustrating a column of a semiconductor device of a fifth embodiment according to the present disclosure.

FIG. 15 is a front view and a bottom view illustrating a column of a semiconductor device of a sixth embodiment according to the present disclosure.

FIG. 16 is a block diagram of an electronic device including a semiconductor device or a mounting substrate according to the present disclosure.

### MODE FOR CARRYING OUT THE INVENTION

Next, modes for carrying out the semiconductor device and the like according to the present disclosure (hereinafter, it is referred to as an “embodiment”) will be described in the following order with reference to the drawings. In the drawings described below, the same or similar parts are denoted by the same or similar reference signs. However, the drawings are schematic, and dimensional ratios and the like of the respective parts do not necessarily match actual ones.] Furthermore, it goes without saying that dimensional relationships and ratios are partly different between the drawings.

1. First Embodiment of Semiconductor Device According to the Present Disclosure

2. Soldering Step of Semiconductor Device of First Embodiment According to the Present Disclosure

3. Second Embodiment of Semiconductor Device According to the Present Disclosure

4. Third Embodiment of Semiconductor Device According to the Present Disclosure

5. Fourth Embodiment of Semiconductor Device According to the Present Disclosure

6. Fifth Embodiment of Semiconductor Device According to the Present Disclosure

7. Sixth Embodiment of Semiconductor Device According to the Present Disclosure

8. Electronic Device Including Semiconductor Device or Mounting Substrate According to the Present Disclosure

### 1. First Embodiment of Semiconductor Device According to the Present Disclosure

### Basic Configuration Example of First Embodiment

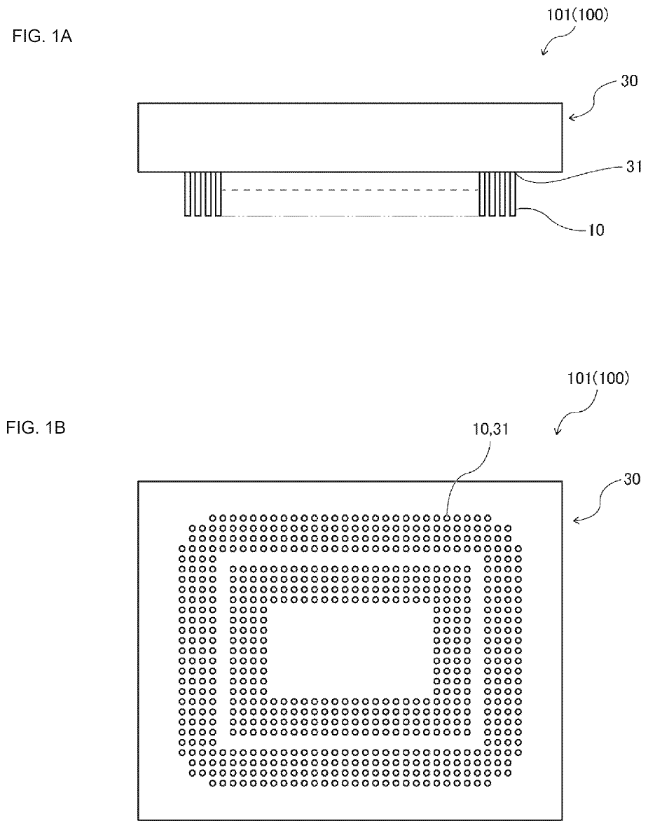

FIGS. 1A and 1B are a front view (side view) and a bottom view illustrating an arrangement example of a column 10 of a semiconductor device 101 according to the present disclosure. In a schematic structure of the semiconductor device 101, as illustrated in FIGS. 1A and 1B, a plurality of columns 10 is suspended from a bottom surface of a substantially rectangular semiconductor package 30 via lands 31. In the example illustrated in FIG. 1B, the dimensions of the semiconductor package 30 are 40 mm in length×50 mm in width. A plurality of lands 31 having a diameter of 0.63 mm is arranged at substantially equal intervals at a pitch of 1.27 mm, and is concentrically arranged in a double rectangular shape.

Note that the semiconductor device 101 is an integrated circuit formed on a silicon substrate, and is, for example, a solid-state imaging device 100, a microprocessor, a memory, a logic circuit, or the like, or an integrated body thereof.

In a semiconductor package 30 illustrated in FIGS. 1A and 1B, a column 10 is soldered to a land 31 formed on the bottom surface. The column 10 is used by being soldered to a land 41 formed on a wiring board 40 described later by a reflow process.

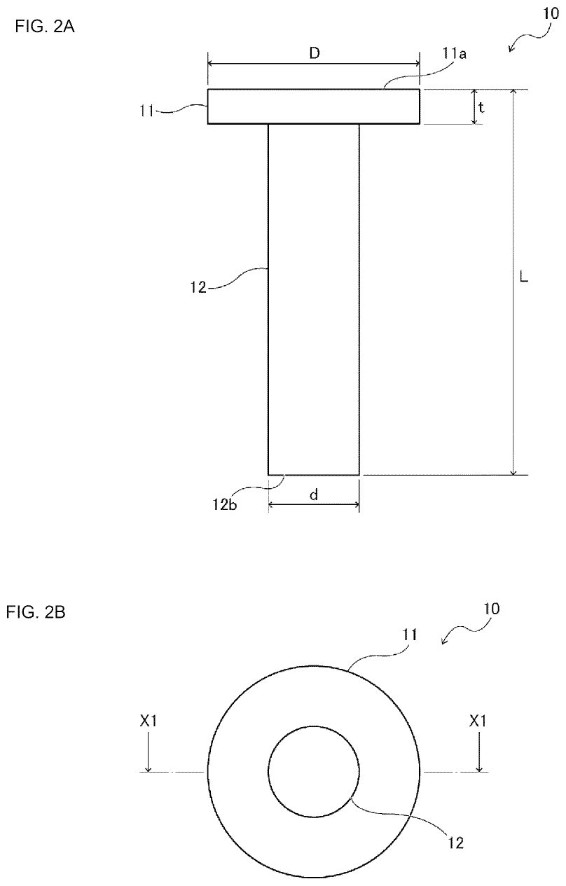

As illustrated in the front view (side view) of FIG. 2A, the column 10 has a shape having a flange portion 11 at the upper end and a substantially cylindrical body portion 12. Then, the flange portion 11 and the body portion 12 are coaxially connected to each other as illustrated in the bottom view of FIG. 2B. Here, the total length of the column 10 is L, the diameter of the flange portion 11 is D, the pedestal thickness of the flange portion 11 is t, and the diameter of the body portion 12 is d.

The column 10 is formed by, for example, cold forging or cold stamping a thin wire of copper (Cu). The cold forging process and the cold stamping process are also called “cold header process”, and is a type of plastic process in which a metal material is deformed into a desired shape by applying a force to the metal material at normal temperature without heating the material. In general, machining by applying a force in a longitudinal direction of a metal material is called “forging”, and machining by applying a force in a lateral direction is called “stamping”.

The column 10 is formed by the processing method as described above, and then plated with nickel gold (NiAu) by electroless plating, for example. This improves solder wettability and improves solderability.

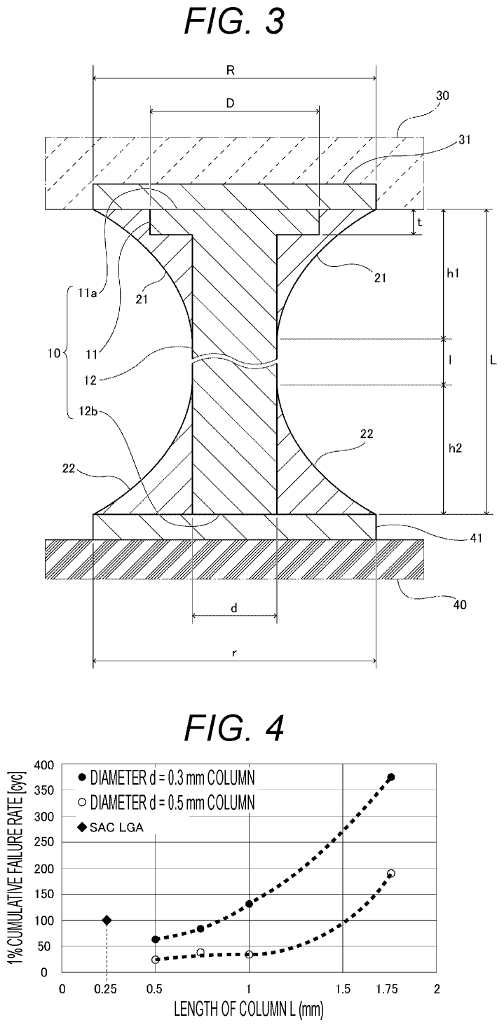

Next, the soldering state of the column 10 of the semiconductor device 101 of the first embodiment will be described with reference to FIG. 3. This drawing is a cross-sectional end view taken along line X1-X1 in FIG. 2.

As illustrated in FIG. 3, an upper end 11a of the flange portion 11 of the column 10 is soldered to the land 31 of the semiconductor package 30 by a first solder 21 to constitute a first solder portion. Here, a diameter of the land 31 of the semiconductor package 30 is defined as R. In this drawing, the diameter R of the land 31 is larger than a diameter D of the flange portion 11.

The column 10 is soldered by the first solder 21 with the upper end 11a of the flange portion 11 abutting on the land 31 of the semiconductor package 30.

Specifically, when the first solder 21 is melted by applying heat, due to wettability thereof, the first solder 21 goes up a peripheral side surface of the flange portion 11 from the upper end 11a of the flange portion 11, and further goes up a peripheral side surface of the body portion 12. Here, a length from a soldering surface of the land 31 to the end of solder wicking at which the first solder 21 reaches is defined as a rising height h1 of the first solder 21.

Furthermore, as illustrated in FIG. 3, a lower end 12b of the body portion 12 of the column 10 is soldered to the land 41 of the wiring board 40 by a second solder 22 to constitute a second solder portion. Here, a diameter of the land 41 of the wiring board 40 is denoted by r. In this drawing, the diameter r of the land 41 is formed to be larger than the diameter d of the body portion 12.

The wiring board 40 is, for example, a printed wiring board on which an electronic component or the like in which conductive wiring is provided on both surfaces or one surface of a substrate of an insulator such as glass epoxy or phenol or an inner layer thereof is not mounted. The wiring board 40 includes a flexible board having flexibility in addition to a rigid board having a hard wiring board.

When the second solder 22 is melted by applying heat, the second solder rises on the peripheral side surface of the body portion 12 from the lower end 12b of the body portion 12 due to the wettability similarly to the first solder 21. Here, the length from the soldering surface of the land 41 to the end of the solder wicking at which the second solder 22 reaches is defined as a rising height h2 of the second solder 22. In this manner, the second solder 22 rises from a lower side to an upper side along the peripheral side surface of the body portion 12.

On the other hand, in FIG. 3, in the relationship between the land 31 and the column 10, the first solder 21 is described as descending from the upper side to the lower side. However, in practice, as illustrated in FIGS. 8 and 9 as described later, soldering by the first solder 21 is performed in a state where FIG. 3 is turned upside down. Thus, similarly to the second solder 22, the first solder 21 also goes along the peripheral side surface of the body portion 12 and rises from the lower side to the upper side. In such a phenomenon, wettability is improved by melting the solder at an appropriate temperature, and the contact angle formed with the soldering surface becomes an acute angle, so that the first solder 21 and the second solder 22 spread along the peripheral side surface of the body portion 12 to be the soldering surface due to surface tension. This is generally called “solder wicking”.

In finishing the first solder 21 and the second solder 22, it is desirable that the first solder 21 and the second solder 22 conform to the lands 31 and 41 as if they are wet. For example, the angle (contact angle) formed between surfaces of the lands 31 and 41 and surfaces of the first solder 21 and the second solder 22 needs to be an acute angle.

Therefore, as illustrated in FIG. 3, it is desirable that a fillet formed by solder wicking forms a smooth curve with a predetermined curvature radius like a foot of a konide volcano such as Mt. Fuji. In this case, the center of curvature of the fillet must be on the side facing the column 10. Moreover, it is desirable that the surface of soldering is not rough and has a smooth metallic gloss.

That is, it is desirable that both the contact angle between the soldering surface of the land 31 and the rising surface of the first solder 21 and the contact angle between the rising surface of the first solder 21 and the peripheral side surface of the body portion 12 at the rising height h1 of the first solder 21 are small.

Similarly, it is desirable that both the contact angle between the soldering surface of the land 41 and the rising surface of the second solder 22 and the contact angle between the rising surface of the second solder 22 and the peripheral side surface of the body portion 12 at the rising height h2 of the second solder 22 are small. Such a shape of soldering can be achieved by appropriately managing the temperature, heating time, and the like of soldering. Details will be described later.

Furthermore, as illustrated in FIG. 3, the total length L of the column 10 needs to be formed to be larger than the sum of the rising height h1 of the first solder 21 and the rising height h2 of the second solder 22. Here, assuming that the sum of the rising height h1 of the first solder 21 and the rising height h2 of the second solder 22 is a length H, H=h1+h2.

Here, assuming that a difference between the total length L and the length H of the column 10 is 1, the total length L is set so that

$$1 = L - H = L - ( h 1 + h 2 ) > 0.$$

Here, the difference 1 between them is referred to as a “bending margin”. In the total length L of the column 10, the upper end 11a of the flange portion 11 and the lower end 12b of the body portion 12 are fixed to the semiconductor package 30 and the wiring board 40 via the land 31 and the land 41 by soldering in the regions of the rising height h1 of the first solder 21 and the rising height h2 of the second solder 22.

As described above, in a case where the semiconductor package 30 is soldered to the land 41 of the wiring board 40 via the column 10, as described above, there may be a problem that peeling or cracking of a soldered portion occurs due to thermal fluctuation in actual use after soldering.

That is, when stress generated by thermal fluctuation is applied to both ends of the column 10, there is a possibility that peeling or cracking occurs at a soldered portion. When such stress is generated, the bending margin l relaxes the stress by elastically deforming the portion of the bending margin l of the body portion 12 of the column 10, and prevents the occurrence of peeling and cracking.

It is considered that the stress generated in the column 10 due to the thermal fluctuation varies depending on factors such as the total length L of the column 10, the diameter D of the flange portion 11, the pedestal thickness t, the diameter d of the body portion 12, the rising height h1 of the first solder 21, the rising height h2 of the second solder 22, and the bending margin l.

Therefore, the optimum dimensional relationship for alleviating the tensile stress, the compressive stress, and the like generated by the thermal fluctuation was obtained by the following experiment.

### [Experimental Result of Stress Relaxation Caused by Thermal Fluctuation]

For these factors, experimental contents and experimental results for obtaining an optimum dimensional relationship will be described below.

FIG. 4 is a graph of data obtained by actually measuring the 1% cumulative failure rate according to the column size of the straight column 10 in the semiconductor device 101 having the outer shape as illustrated in FIG. 1 with the column 10 having no flange portion 11 (hereinafter, referred to as a “straight column”) as the shape of the column 10. In the drawing, the horizontal axis represents the total length L of the straight column 10, and the vertical axis represents the 1% accumulated failure rate.

Here, the 1% cumulative failure rate is represented by the number of cycles in the temperature cycle test until the number of occurrences of failure such as peeling or cracking at a soldering spot of the column 10, which is generally called “column collapse”, reaches 1% in the cumulative number among all the columns. The test conditions of the temperature cycle test are so that −25° C. and 100° C. are alternately applied for 10 minutes, and this cycle is continuously repeated with this cycle as one cycle.

As the test sample, a straight column 10 having a diameter d of 0.3 mm and 0.5 mm was used. In each test sample, the total length L was changed to 0.5 mm, 0.75 mm, 1.0 mm, and 1.75 mm. Furthermore, a land glid array (SAC LGA) terminal of a Sn—Ag—Cu land was added to the test sample for comparison with these test samples. The SAC LGA terminal has a diameter of 0.63 mm and a height of 0.25 mm. Each of these terminals is soldered to the land 31 on the bottom surface of the semiconductor package 30, and in this state, is soldered to the wiring board 40.

The following results were obtained from the test data of FIG. 4 in which the temperature cycle test was performed on each of the above test samples.

(1) In the test sample in which the diameter d of the column 10 is 0.5 mm, the cumulative failure rate reaches 1% in about 40 cycles when the total length L of the column 10 is between 0.5 mm and 1.0 mm.

However, when the total length L is 1.75 mm, the cumulative failure rate reaches 1% in about 190 cycles.

(2) In the test sample in which the diameter d of the column 10 is 0.3 mm, the cumulative failure rate reaches 1% in about 60 cycles when the total length L of the column 10 is 0.5 mm. Furthermore, when the total length L of the column 10 is 1.0 mm, the cumulative failure rate reaches 1% in about 130 cycles. Further, when the total length L of the column 10 was 1.75 mm, the test was performed up to about 375 cycles, but the cumulative failure rate at this number of cycles was 0.6% and did not reach 1.0%.

(3) The SAC LGA terminal reaches a cumulative failure rate of 1% in about 100 cycles.

(4) From the above results, it was found that the cumulative failure rate is smaller when the diameter d of the column 10 is 0.3 mm than 0.5 mm.

(5) Furthermore, it was also found that the longer the total length L of the column 10, the smaller the 1% cumulative failure rate.

(6) When the diameter d of the column 10 was 0.3 mm and the total length L was 1.0 mm, it was found that the 1% cumulative failure rate was smaller in the straight column 10 than in the SAC LGA terminal.

Accordingly, next, a temperature cycle test was performed on each of the test samples U, V, W, and X of the column 10 having the flange portion 11 in which the diameter D of the flange portion 11 was 0.3 mm. Table 1 illustrates a list of dimensions of each part of each of the test samples U, V, W, and X used in the test.

TABLE 1
(mm)

| Part | U | V | W | X |
|---|---|---|---|---|
| D | 0.3 | 0.3 | 0.3 | 0.3 |
| d | 0.15 | 0.2 | 0.2 | 0.15 |
| t | 0.05 | 0.1 | 0.1 | 0.05 |
| L | 0.55 | 0.6 | 1.04 | 1.0 |

In the test sample U, the diameter D of the flange portion 11 is 0.3 mm, the diameter d of the body portion 12 is 0.15 mm, the pedestal thickness t of the flange portion 11 is 0.05 mm, and the total length L is 0.55 mm.

In the test sample V, the diameter D of the flange portion 11 is 0.3 mm, the diameter d of the body portion 12 is 0.2 mm, the pedestal thickness t of the flange portion 11 is 0.1 mm, and the total length L is 0.6 mm.

In the test sample W, the diameter D of the flange portion 11 is 0.3 mm, the diameter d of the body portion 12 is 0.2 mm, the pedestal thickness t of the flange portion 11 is 0.1 mm, and the total length L is 1.04 mm.

In the test sample X, the diameter D of the flange portion 11 is 0.3 mm, the diameter d of the body portion 12 is 0.15 mm, the pedestal thickness t of the flange portion 11 is 0.05 mm, and the total length L is 1.0 mm.

Furthermore, the diameter R of the land 31 of the semiconductor package 30 to be soldered is 0.6 mm, and the diameter r of the land 41 of the wiring board 40 is also 0.6 mm.

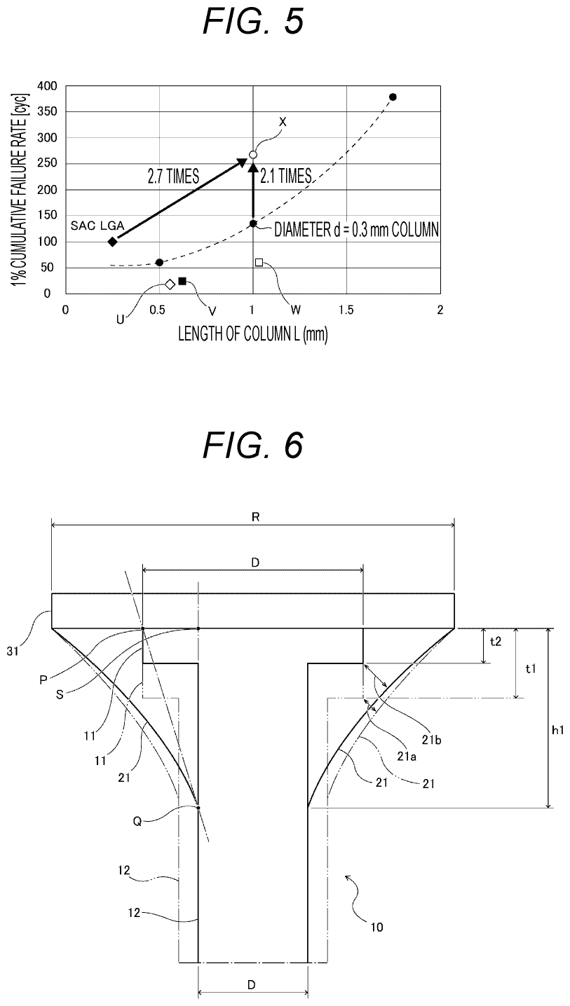

FIG. 5 is a graph illustrating the results of the temperature cycle test performed on each of the test samples U, V, W, and X. In this drawing, as in FIG. 4, the horizontal axis represents the total length L of the column 10, and the vertical axis represents the 1% cumulative failure rate.

The following results were obtained from the test data illustrated in FIG. 5 in which the temperature cycle test was performed for each of the test samples U, V, W, and X illustrated in Table 1 above.

(1) In all of the test samples U, V, and W, the cumulative failure rate reaches 1% with the number of cycles smaller than that of the straight column 10 having a diameter d of 0.3 mm illustrated in FIG. 4. For example, the test sample U has 10 several cycles, the test sample V has about 20 cycles, and the test sample W has about 60 cycles.

(2) However, it was found that, in the test sample X, when the diameter d of the body portion 12 is reduced from 0.2 mm to 0.15 mm and the pedestal thickness t of the flange portion 11 is reduced from 0.1 mm to 0.05 mm with respect to the test sample W, the 1% cumulative failure rate is dramatically improved to about 270 cycles.

(3) The improvement ratio of the test sample X is about 2.1 times that of the straight column 10 in which the diameter d of the column 10 is 0.3 mm and the total length L is 1.0 mm illustrated in FIG. 4.

Furthermore, it is about 2.7 times that of the SAC LGA terminal described in FIG. 4.

(4) Furthermore, when comparing the test sample X with the test sample U, the diameter d of the body portion 12 was 0.15 mm, the pedestal thickness t was 0.05 mm, and both were made the same, and the total length L was increased from 0.55 mm to 1.0 mm, thereby obtaining the same improvement effect. Therefore, if the total length L is further longer than 1.0 mm, it is expected that the 1% cumulative failure rate can be further improved.

However, when the total length L is increased, the height of the semiconductor package 30 increases accordingly, which is not practical.

(5) From the above, it was found that, in the test sample W, when the diameter d of the body portion 12 is reduced from 0.2 mm to 0.15 mm, the pedestal thickness t of the flange portion 11 is reduced from 0.1 mm to 0.05 mm, and the total length L is 1.0 mm, the 1% cumulative failure rate can be dramatically improved.

From the above experimental results, the reason why the 1% cumulative failure rate can be dramatically improved in the test sample X is considered as follows.

The first reason is that the thickness of the pedestal thickness t of the flange portion 11 is formed to be thin. This will be described with reference to FIG. 6. Note that, in FIG. 6, the dimensional relationship of the test sample W is represented by two-dot chain lines, and the dimensional relationship of the test sample X is represented by a solid line, both of which are represented by equal scales. For example, as illustrated in the example of the test sample W in FIG. 6, in a case where the thickness of the pedestal thickness t of the flange portion 11 is t1 (0.1 mm), the first solder 21 rises from the peripheral end of the land 31 having the diameter R to the rising height h1 of the first solder 21 to form a fillet.

However, as in the example of the test sample W, in a case where the thickness of the pedestal thickness t is t1 (0.1 mm), as illustrated by the two-dot chain lines in FIG. 6, since the pedestal thickness t is as thick as the thickness t1, the solder thickness 21a of the first solder 21 at a peripheral edge portion of the pedestal thickness t becomes thin. Therefore, the soldering strength of the portion having the thinned thickness 21a becomes weak. For this reason, it is considered that the cumulative failure rate reached 1% in about 50 cycles in the temperature cycle test.

On the other hand, in the example of the test sample X, the thickness of the pedestal thickness t is t2 (0.05 mm), and as illustrated by the solid line in FIG. 6, since the pedestal thickness t is as thin as the thickness t2, the solder thickness 21b of the first solder 21 at the peripheral edge portion of the pedestal thickness t becomes thick. Therefore, the soldering strength of the portion having the increased thickness 21b is increased. For this reason, it is considered that the 1% cumulative failure rate was improved to about 270 cycles in the temperature cycle test.

As described above, by reducing the thickness of the pedestal thickness t of the flange portion 11, the first solder 21 easily wraps around the back surface of the flange portion 11, and the first solder 21 easily rises. Furthermore, it is considered that since the first solder 21 on the back surface of the flange portion 11 and the peripheral edge portion of the pedestal thickness t can be thickly soldered, the flange portion 11 can be firmly fixed.

Therefore, when this is generalized, as illustrated in FIG. 6, when a straight line PQ connecting a peripheral edge P of an upper surface of the flange portion 11 and a peripheral edge Q, which is the position of the rising height h1 of the first solder 21, is drawn, it is desirable that the flange portion 11 is covered with the first solder 21 and the portion of the pedestal thickness t of the flange portion 11 is present on the straight line PQ. That is, it is necessary that the flange portion 11 which is a metal portion exists on the straight line connecting the upper end of the column 10 and the solder rising height h1, and it is desirable that the flange portion 11 is covered with the first solder 21.

As a reason for this, it is considered that the effect of suppressing the movement of the column 10 is large by covering and fixing a back side portion of the pedestal thickness t of the flange portion 11 with the first solder 21.

Furthermore, the starting point of the crack of the first solder 21 is usually the peripheral edge P where the land 31 and the peripheral side surface of the column 10 are in contact with each other. For example, when a force in a left direction in this drawing acts on the body portion 12 due to stress caused by thermal fluctuation, the peripheral edge P becomes a fulcrum or an action point. Furthermore, when a force in a left direction is applied, the right peripheral edge P in the drawing at a symmetrical position of the peripheral edge P serves as a fulcrum or an action point. Even when a force in any direction acts, any one of the peripheral edges P serves as a fulcrum or an action point.

Here, when an intersection S between a vertical line passing through the peripheral edge Q of the body portion 12 and the upper end 11a of the flange portion 11 is defined, since a straight line QS and the straight line PQ form a predetermined angle, a reaction force is generated against the stress in the right direction or the left direction. As a result, it is considered that the stress is reduced. That is, the straight line PQ acts as a “diagonal” with respect to the stress in the left-right direction, and prevents “column collapse” due to the stress.

On the other hand, in the case of the straight column 10, since the straight column is supported by the straight line QS, such a diagonal effect cannot be obtained.

The above idea can also be applied to a case where the second flange portion 11L is provided at the lower end 12b of the body portion 12 of the column 10 in a second embodiment described later.

The second reason is that the total length L of the column 10 is formed to be long. By increasing the total length L, the length of the “bending margin l” where solder wicking is not performed in the body portion 12 of the column 10 is secured. Therefore, it is considered that the stress generated by the thermal fluctuation accompanying the temperature cycle or the like is alleviated by the “bending effect” of the bending margin l of the body portion 12.

Here, the “bending effect” means that the stress generated by the thermal fluctuation is relaxed by the elastic deformation of the portion of the bending margin l. The thermal fluctuation in actual use is caused by elongation of the metal at a high temperature and shrinkage of the metal at a low temperature. The bending margin l of the body portion 12 of the column 10 alleviates the stress caused by such expansion and contraction.

Accordingly, an appropriate dimensional relationship of the column 10 having the flange portion 11 capable of appropriately alleviating the stress by the bending effect can be expressed as follows as a conclusion. As illustrated in FIG. 3, when the diameter of the land 31 of the semiconductor package 30 is denoted by R, the diameter of the flange portion 11 of the column 10 is denoted by D, the total length of the column 10 is denoted by L, the diameter of the body portion 12 of the column 10 is denoted by d, the diameter of the land 41 of the wiring board 40 to which the lower end 12b of the body portion 12 is bonded is denoted by r, the rising height of the first solder 21 is denoted by h1, the rising height of the second solder 22 is denoted by h2, and the bending margin of the column 10 is denoted by l, it is necessary that
the land 31 of the semiconductor package 30, the column 10 having the flange portion 11 at the upper end, the first solder 21, the second solder 22, and the land 41 of the wiring board 40 satisfy
the relationship of 3D/2≤R≤2D, the relationship of 3d≤r≤4d, and
the relationship of L≥1+H. However, H is a constant satisfying H=h1+h2, and is 0.48 from an actual measurement value of a cross section in the axial direction of the actual sample when nickel gold (NiAu) plating is applied to the column 10. Incidentally, the rising height h1 of the first solder 21 and the rising height h2 of the second solder 22 are 0.225 and 0.255, respectively.

Here, the fact that the length of the total length L has a large influence on the bend will be described below. When the amount by which the bending margin l is deformed by receiving stress is defined as a “bending amount δ” (it is a “deflection amount δ” in material mechanics), the bending amount δ can be described from an expression of a second moment of area.

The second moment of area is an amount representing uneasiness of deformation of a beam (beam) member with respect to a bending moment, and is represented by a symbol “I” similarly to the moment of inertia representing uneasiness of rotation of a rigid body (object) in mechanics. The second moment of area has a value corresponding to each shape of the cross section of the beam member. Since the shape of the column 10 according to the present disclosure is a solid round bar, the second moment of area thereof is expressed by I=(πd⁴)/64.

Furthermore, the bending amount δ of the column 10 is expressed by δ=(WL³)/(3EI).

In the expression of the bending amount δ, W is a load applied to the column 10, and corresponds to, for example, a stress applied to the position of the rising height h2 of the second solder 22 of the body portion 12 of the column 10. L is the total length of the beam. This corresponds to the bending margin l of the column 10. E is a longitudinal elastic modulus (Young's modulus). This corresponds to the Young's modulus of the material forming the column 10. I is the second moment of area.

Therefore, when the expression of the second moment of area I is substituted into the expression of the bending amount δ and L is denoted by l, the following expression is obtained:

$$\begin{matrix}the bending amount δ = ( {WL}^{3} ) / ( 3 EI ) = \{ ( W {1}^{3} ) / ( 3 E ) \} \times \{ 64 / ( π {d}^{4} ) \} \\ = ( 64 W {1}^{3} ) / ( 3 π {Ed}^{4} ) ∝ {1}^{3} / {d}^{4} .\end{matrix}$$

From this equation, it can be seen that the bend amount δ is proportional to the cube of the bending margin l. That is, when the bending margin l is doubled, the bending amount δ becomes eight times. Here, since the bending margin l is 1=L−H and the constant H is constant, the bending margin l can also be increased by increasing the total length L. Therefore, by forming the total length L of the column 10 to be long, it is possible to relax the stress by the bending effect.

Furthermore, it can be seen that the bending amount δ is inversely proportional to the fourth power of the diameter d of the body portion 12 of the column 10. That is, when the diameter d is ½ times, the bending amount δ is 16 times.

Note that the effect of reducing the diameter d will be described in detail below.

A third reason is that the diameter d of the body portion 12 is formed to be small as described above. As described in the above equation, the bending amount δ is inversely proportional to the fourth power of the diameter d of the body portion 12 of the column 10.

In the example illustrated in FIG. 4, since the diameters d are 0.3 mm and 0.5 mm, the ratio of the diameters d and d is 0.3/0.5=0.6. Therefore, the ratio of the bending amount δ between the diameter d of 0.3 mm and 0.5 mm is 1/0.6⁴=1/0.13=7.7 times.

Therefore, when the diameter d is reduced, the bending effect can be greatly exhibited. In other words, the length of the bending margin l is also shortened. For this reason, in a case where the total length L of the column 10 is constant, the effect of the deflection bending margin l increases accordingly, and the stress caused by the thermal fluctuation can be further alleviated.

In this manner, the bending amount δ changes greatly only by slightly changing the total length L or the diameter d.

Although the improvement effect when the diameter d is changed from 0.5 mm to 0.3 mm described in FIG. 4 and the dramatic improvement effect from the test sample W to the test sample X described in FIG. 5 may seem strange at first glance, the fact that such an improvement effect can be obtained can also support the tendency from the mathematical formula.

As described above, by appropriately selecting the dimensions of each part of the column 10 having the flange portion 11, the 1% cumulative failure rate in the temperature cycle test can be improved.

Moreover, by providing the flange portion 11, the following effects can be obtained.

First, it is possible to reduce the diameter d of the body portion 12, which is the substantial diameter of the column 10, while maintaining a large bonding area between the semiconductor package 30 and the land 31. Moreover, by forming the pedestal thickness t of the flange portion 11 to be thin, the back surface of the flange portion 11 can be thickly covered with the first solder 21, and the occurrence of solder peeling, cracks, and the like can be prevented.

Second, since the diameter d of the body portion 12, which is the substantial diameter of the column 10, can be reduced while the area bonded to the land 31 is maintained wide, the necessary bending margin l can be shortened, and the total length L of the column 10 can be shortened. Thus, it is possible to suppress the height when the semiconductor package 30 is soldered to the wiring board 40. On the other hand, in a case where the entire length L is kept as it is, the bending margin l can be secured for a long time, so that the effect of alleviating the stress caused by the thermal fluctuation can be further enhanced.

### 2. Soldering Step of Semiconductor Device of First Embodiment According to the Present Disclosure

### [Soldering of Column by First Solder]

Next, an example of a soldering process of the semiconductor device 101 of the first embodiment according to the present disclosure will be described. First, soldering by the first solder 21 will be described. The semiconductor package 30 of the semiconductor device 101 is prepared in another process. A plurality of lands 31 for soldering the flange portion 11 of the column 10 by the first solder 21 is arranged on the bottom surface of the semiconductor package 30.

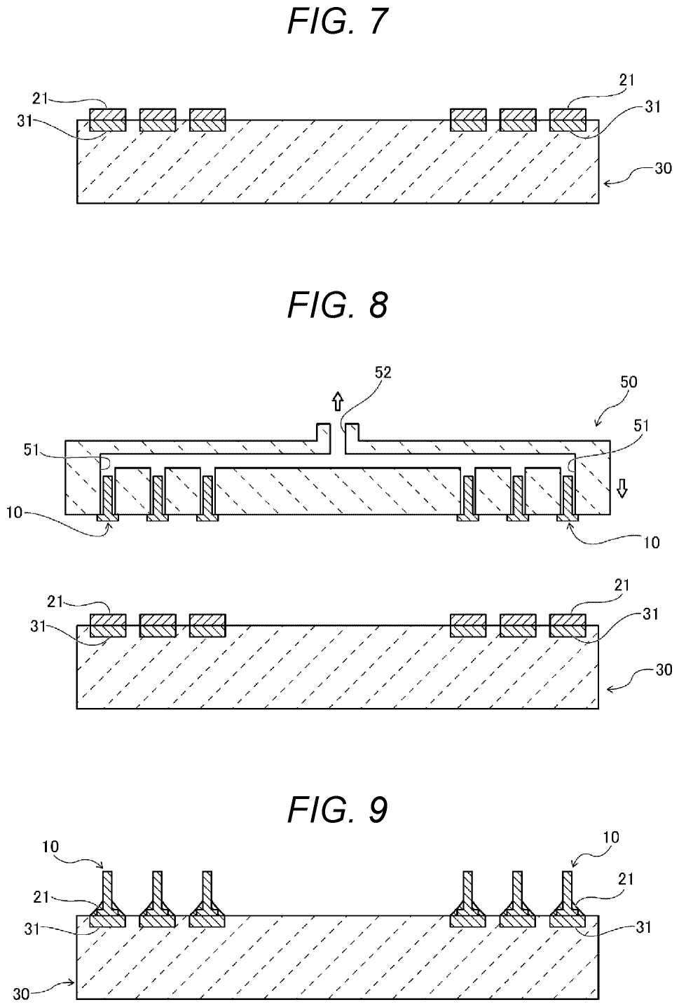

Next, the column 10 is soldered to each of the plurality of lands 31 arranged on the bottom surface of the semiconductor package 30 by the first solder 21. In soldering, the first solder 21 is applied to the land 31 as illustrated in the explanatory view of the cross section of FIG. 7. The first solder 21 is a paste-like cream solder (it is also referred to as “solder paste”) at this time.

The cream solder is formed into a paste by mixing fine solder particles of several microns with a flux. The first solder 21 is applied by a mode of, for example, printing by screen printing or the like following the arrangement and shape of the land 31 using a cream solder printing machine or the like.

Next, as illustrated in FIG. 8, the column 10 placed on the part feeder (not illustrated) is adsorbed by a plurality of small hole-shaped suction nozzles 51 formed in a suction head 50 of a soldering jig corresponding to the arrangement of the lands 31. The suction of the columns 10 to the suction nozzles 51 is performed by exhausting air sucked from the suction nozzles 51 from suction ports 52 provided in the suction head 50. That is, when air is sucked from the suction ports 52, the columns 10 are sequentially sucked by the suction nozzles 51 from the lighter body portion 12 side because the flange portion 11 is heavier.

Next, when the suction of the columns 10 to the suction nozzles 51 is completed, the suction head 50 is lowered onto the lands 31 of the semiconductor package 30 to which the first solder 21 is applied. Then, the column 10 is collectively placed by bringing the upper end 11a of the flange portion 11 of the column 10 into contact with the facing creamy first solder 21 and stopping suction.

Next, the pads 31 on the lower surface of the semiconductor package 30 and the columns 10 are soldered with the first solder 21. This soldering is performed by a reflow process in which the semiconductor package 30 with the columns 10 placed thereon is placed on a conveyor (not illustrated) and passed through a reflow furnace (not illustrated).

In the reflow step, temperature management of soldering is performed according to a predetermined temperature profile. For example, the surface temperature of the semiconductor package 30 is set to about 180 to 190° C., and preheating is performed for about 60 to 120 seconds. Next, the temperature is gradually increased, and a state in which the surface temperature of the semiconductor package 30 is about 230 to 260° C. (peak temperature) is continued for about 30 to 50 seconds. Thus, the paste-like first solder 21 is melted and soldered. Furthermore, the flux is vaporized and discharged from a duct (not illustrated). Thereafter, the first solder 21 is solidified by lowering the temperature. Thus, as illustrated in FIG. 9, the column 10 is soldered to the semiconductor package 30 by the first solder 21.

Note that, precisely, since the temperature profile differs for each semiconductor package 30 or depending on the dimensional relationship of the column 10 described above, it is necessary to perform test confirmation and condition setting in advance for each semiconductor package 30. By appropriately setting the temperature profile, the rising height h1 of the first solder 21 and the shape of the fillet are managed.

Therefore, the temperature, heating time, and the like of the reflow step described above are merely examples. Note that, in a case where the first solder 21 is not a non-washing solder or the like, washing is performed after soldering.

Through the soldering step as described above, the column 10 can be soldered to the land 31 of the semiconductor package 30 by the first solder 21.

Note that, in FIG. 8 described above, the process example has been described in which the column 10 is adsorbed by each of the suction nozzles 51 formed in the suction head 50, and then the upper end 11a of the flange portion 11 of the column 10 is brought into contact with the creamy first solder 21 and collectively placed. On the other hand, the body portion 12 of the column 10 may be gripped by a mounter (not illustrated), and the flange portion 11 side of the column 10 may be individually placed on the creamy first solder 21 applied to the land 41 of the wiring board 40.

Here, as the first solder 21 used in the soldering step described above, low-temperature solder having a melting point equivalent to that of the second solder 22 used when the semiconductor device 101 is soldered to the lands 41 of the wiring board 40 is used.

Low-temperature solder (low-melting point solder) generally has a melting point lower than that of eutectic solder (Tin (Sn) 63%, lead (Pb) 37%) (184° C. or lower). In leaded solder, the melting point increases as the amount of lead component increases as compared with the eutectic solder. Furthermore, the melting point increases even if the lead component is reduced as compared with the eutectic solder. That is, in the case of the leaded solder, the melting point of the eutectic solder is the lowest. Therefore, solder other than eutectic solder is generally classified as high-temperature solder.

Examples of solder based on tin (Sn) or lead (Pb) include low-temperature solder having a lower melting point by blending cadmium (Cd), bismuth (Bi), indium (In), or the like.

Furthermore, lead-free solder has been put into practical use from the viewpoint of environmental protection. As the name suggests, the lead-free solder is solder containing no lead (Pb). The lead-free solder contains tin (Sn) as a main component, and contains other metals such as silver (Ag) and copper (Cu) in tin. The first solder 21 and the second solder 22 used for soldering the semiconductor device 101 of the first embodiment according to the present disclosure only needs to be low-temperature solder, and it does not matter whether it is leaded solder or lead-free solder.

### [Soldering of Semiconductor Device by Second Solder]

Next, soldering of the semiconductor device 101 to the wiring board 40 by the second solder 22 will be described. The wiring board 40 to which the lower ends 12b of the body portions 12 of the columns 10 are soldered by the second solder 22 is separately prepared.

The creamy second solder 22 is applied to the lands 41 of the wiring board 40 by a process similar to that applied to the lands 31 of the semiconductor package 30.

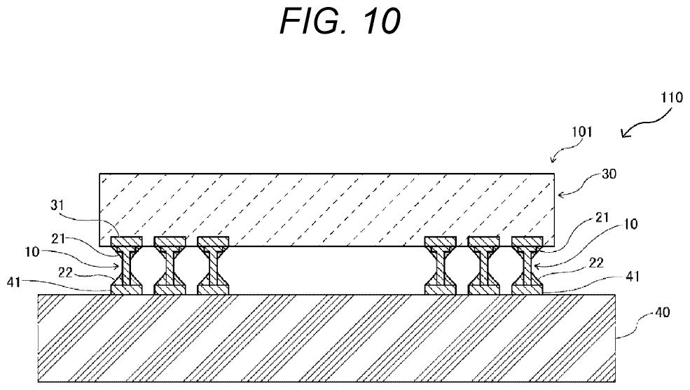

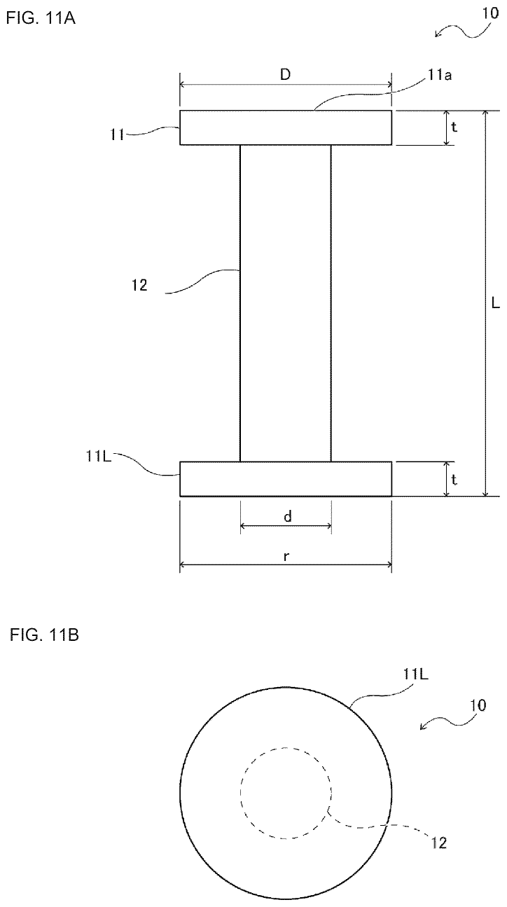

Here, in the reflow step, the creamy second solder 22 is melted by the temperature inside the furnace in the reflow furnace according to a predetermined temperature profile. Then, after causing solder wicking from the lands 41 and the lower ends 12b of the body portions 12 of the columns 10 to the rising height h2 of the second solder 22, the solder is cooled and solidified according to the temperature profile in the furnace. Thus, as illustrated in FIG. 10, the semiconductor package 30 is soldered to the lands 41 of the wiring board 40 by the second solder 22.

Note that details of the reflow step are similar to those of the soldering by the first solder 21, and thus the description thereof is omitted.

Thereafter, if necessary, cleaning is performed, and a predetermined inspection process is performed, whereby the mounting substrate 110 in which the semiconductor device 101 is mounted on the wiring board 40 can be obtained.

As described above, soldering by the second solder 22 of the semiconductor device 101 of the first embodiment according to the present disclosure as illustrated in FIGS. 3 and 10 can be performed.

Note that, although the description is omitted, it goes without saying that when the semiconductor device 101 is soldered to the wiring board 40 using the second solder 22, other semiconductor devices besides the semiconductor device 101 and electronic components such as resistors and capacitors are also soldered to the wiring board 40 by the second solder 22 at the same time.

Here, it is important that since the melting point of the first solder 21 is equivalent to the melting point of the second solder 22, the first solder 21 also melts according to the temperature profile in the furnace at the time of soldering by the second solder 22, and is cooled and solidified according to the temperature profile in the furnace similarly to the second solder 22.

As described above, at the time of soldering by the second solder 22, by melting the first solder 21 that has already been soldered again, it is possible to remove all residual stresses that may occur in the first solder 21 at the time of soldering by the second solder 22. That is, this makes it possible to remove residual stress that causes peeling of solder, cracks, and the like.

Furthermore, in soldering with the second solder 22, the first solder 21 also melts, but since the flange portion 11 is provided at the upper end of the column 10, the upper end 11a of the flange portion 11 is kept in contact with the soldering surface of the land 31. Moreover, the melted first solder 21 covers the back surface of the flange portion 11 of the column 10, and the first solder 21 covers up to the region of the rising height h1 due to the solder wicking. For this reason, the circumferential length in contact with the first solder 21 is longer than the circumferential length in contact with the second solder 22. Therefore, the force acting on the flange portion 11 due to the surface tension is larger than the force acting on the lower end 12b of the body portion 12. Thus, the entire flange portion 11 corresponding to the head of the column 10 is pulled toward the land 31 as if being held by the first solder 21. Accordingly, even when the first solder 21 is in a molten state, the column 10 does not fall down during soldering.

Such an effect of the first embodiment according to the present disclosure cannot be obtained by the technology disclosed in Patent Document 1 and the technology disclosed in Patent Document 2. For example, in Patent Document 1, pins of a semiconductor device are soldered to soldering parts arranged on a lower surface of a wiring board 40 by a high melting point solder material. Furthermore, in Patent Document 2, connection terminals (pin) of a semiconductor device are connected to lower electrodes arranged on a lower surface of a substrate including ceramic by brazing.

As described above, since the high melting point solder or brazing is joined at a higher temperature than the low temperature solder, the effect of removing the residual stress generated at the time of soldering to the wiring board 40 as in the technology according to the present disclosure cannot be exhibited.

### 3. Second Embodiment of Semiconductor Device According to the Present Disclosure

In a semiconductor device 101 of a second embodiment according to the present disclosure, as illustrated in FIG. 11, a column 10 has a flange portion 11, and a lower end 12b of a body portion 12 is also provided with a second flange portion 11L similar to the flange portion 11. That is, the column 10 is configured to be soldered to the land 41 of the wiring board 40 by the second solder 22 via the second flange portion 11L provided at the lower end 12b of the column 10. Other configurations are similar to those of the first embodiment, and thus description thereof is omitted.

Furthermore, the step of soldering the flange portion 11 of the column 10 to the land 31 of the semiconductor package 30 is the same as that of the first embodiment described above except that the suction nozzle 51 of the suction head 50 of the soldering jig is configured to adsorb the second flange portion 11L and the body portion 12 of the column 10 as they are so that the upper end 11a of the flange portion 11 can be exposed, and thus the description thereof will be omitted.

Note that, in the column 10 having the second flange portion 11L, in a case where the flange portion 11 and the second flange portion 11L have the same diameter D, since the upper and lower sides are symmetric, the upper and lower sides do not need to be distinguished. Therefore, the suction nozzle 51 may adsorb the column 10 from either the upper or lower direction.

Here, an appropriate dimensional relationship of the column 10 having the flange portion 11 and the second flange portion 11L capable of appropriately alleviating the stress by the bending effect can be expressed as follows as a conclusion.

From FIGS. 3 and 10, when the diameter of the land 31 of the semiconductor package 30 is denoted by R, the respective diameters of the flange portion 11 and the second flange portion 11L of the column 10 are denoted by D and Di, the total length of the column 10 is denoted by L, the diameter of the land 41 of the wiring board 40 is denoted by r, the rising height of the first solder 21 is denoted by h1, the rising height of the second solder 22 is denoted by h2, and the bending margin of the column 10 is denoted by l, it is necessary that
the land 31 of the semiconductor package 30, the column 10 having the flange portion 11 and the second flange portion 11L at both ends, the first solder 21, the second solder 22, and the land 41 of the wiring board 40
satisfy a relationship of 3D/2≤R≤2D, and
satisfy a relationship of L≥1+H.

However, H is a constant satisfying H=h1+h2, and is 0.48 when nickel gold (NiAu) plating is applied to the column 10. Incidentally, the rising height h1 of the first solder 21 and the rising height h2 of the second solder 22 are 0.225 and 0.255, respectively.

Furthermore, in a case where the diameter D of the flange portion 11 of the column 10 and the diameter Di of the second flange portion 11L satisfy D=D_{L}, it is sufficient if the above formula is satisfied. However, in a case where D≠D_{L}, it is necessary to further satisfy the relationship of 3D_{L}/2≤r≤2D_{L}.

Similarly to the first embodiment, the column 10 is configured to have the above relationship.

Note that the above formula in the second embodiment is applied when the diameter R of the land 31 and the diameter r of the land 41 are substantially R=r. Therefore, in the case of R≠r, the formula described in the first embodiment is applied.

In the second embodiment, since the second flange portion 11L is provided at the lower end 12b of the body portion 12 of the column 10 as described above, the area to be bonded to the land 41 can be increased similarly to the flange portion 11 provided at the upper end of the column 10. For this reason, the back surface of the second flange portion 11L and the peripheral edge portion of the pedestal thickness t can be soldered thickly with the second solder 22. Thus, the second flange portion 11L can be firmly fixed, and the stress caused by the thermal fluctuation can be further alleviated.

Furthermore, since the second flange portion 11L is provided at the lower end 12b of the body portion 12, the column 10 can stably sit on the land 41 when the column 10 is soldered to the land 41, and the column 10 can be prevented from falling down at the time of soldering.

Since the other configurations are similar to those of the first embodiment, the description thereof will be omitted.

### 4. Third Embodiment of Semiconductor Device According to the Present Disclosure

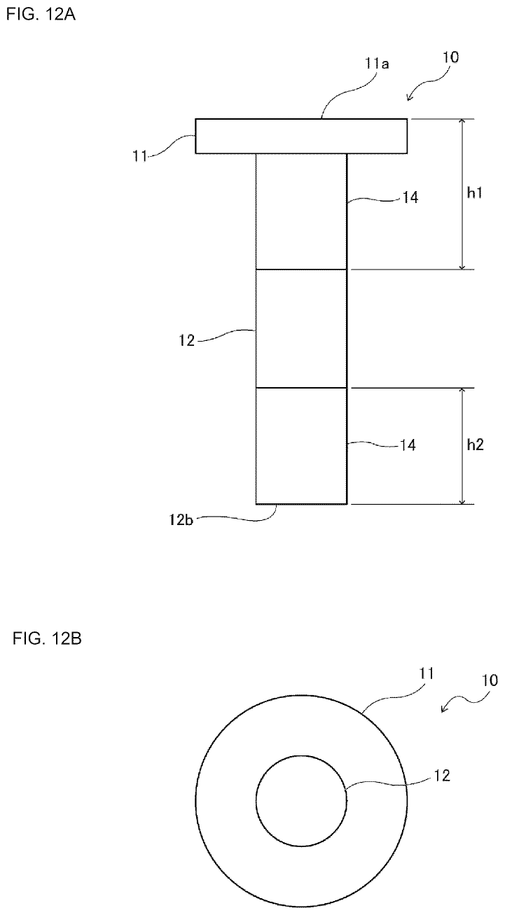

In a semiconductor device 101 of a third embodiment according to the present disclosure, as illustrated in FIG. 12, a solder suction band 14 is formed in a region from an upper end 11a of a flange portion 11 of a column 10 to a rising height h1 of a first solder 21 and a region from a lower end 12b of a body portion 12 to a rising height h2 of a second solder 22. Specifically, the solder suction band 14 is plated with nickel gold (NiAu) to provide a band that facilitates solder wicking. That is, nickel gold (NiAu) plating is applied to the solder suction band 14, which is a region to allow solder wicking, in order to improve solder wettability, and nickel gold (NiAu) plating is not applied to a region other than the solder suction band 14.

Thus, in the soldering step with the first solder 21 and the second solder 22, it is possible to reliably solder the first solder 21 and the second solder 22 plated with nickel gold (NiAu) to the rising heights h1 and h2, respectively. In addition, it is possible to perform control so as not to cause variations in the rising heights h1 and h2 of the first solder 21 and the second solder 22.

Furthermore, the solder suction band 14 may be formed in any of a region having the rising height h1 of the first solder 21 from the upper end 11a of the flange portion 11 of the column 10 and a region having the rising height h2 of the second solder 22 from the lower end 12b of the body portion 12.

Since the other configurations are similar to those of the first embodiment, the description thereof will be omitted.

### 5. Fourth Embodiment of Semiconductor Device According to the Present Disclosure

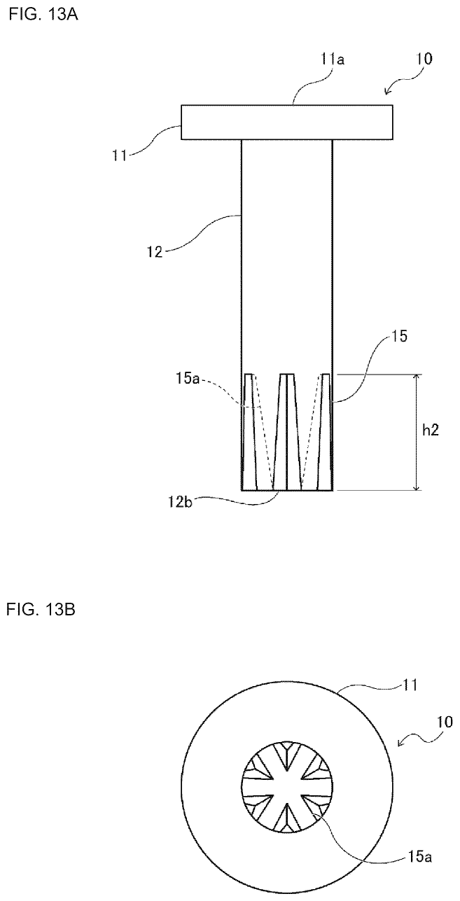

In a semiconductor device 101 of a fourth embodiment according to the present disclosure, as illustrated in FIG. 13, grooves 15a are formed as solder suction bands 15 in a region from a lower end 12b of a body portion 12 of a column 10 to a rising height h2 of a second solder 22. As the grooves 15a, as illustrated in the bottom view of the column 10 in FIG. 13B, a plurality of grooves 15a having a V-shaped cross section is formed on the peripheral side surface of the region from the lower end 12b of the body portion 12 of the column 10 to the rising height h2 of the second solder 22, the grooves being narrower and shallower toward the upper side.

By forming the grooves 15a, the second solder 22 melted at an appropriate temperature has an acute contact angle, and thus can cause solder wicking up to the rising height h2 of the second solder 22 along the grooves 15a due to surface tension.

Therefore, it is possible to reliably perform soldering up to the rising height h2 of the second solder 22. In addition, it is possible to perform control so that the rising height h2 of the second solder 22 does not vary.

Although the V-shaped grooves have been described as an example in FIG. 13, the grooves 15a are not limited to the V-shaped grooves, and may be round grooves, U-shaped grooves, square grooves, or the like. Furthermore, these grooves may be formed so that the width and depth of the upper end and the lower end of the groove are the same. Furthermore, in FIG. 13, an example in which six grooves 15a are formed has been described, but the number of grooves is not limited to six.

Since the other configurations are similar to those of the first embodiment, the description thereof will be omitted.

### 6. Fifth Embodiment of Semiconductor Device According to the Present Disclosure

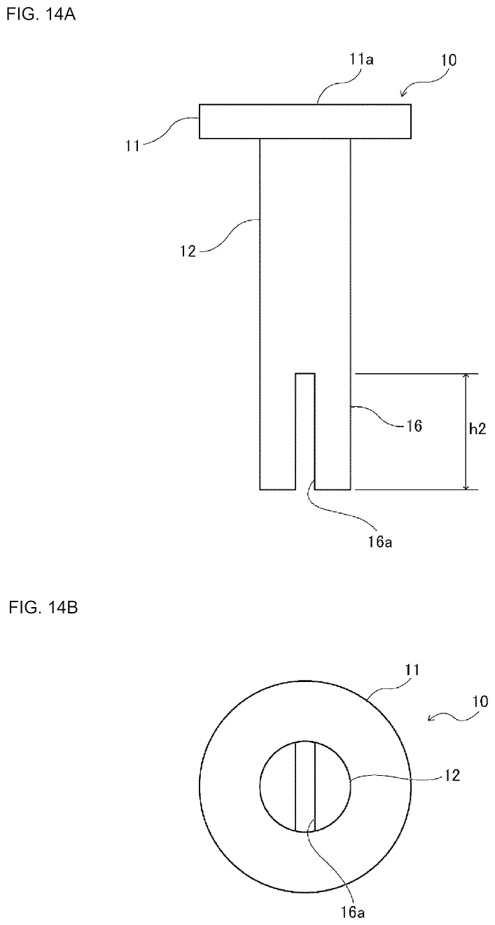

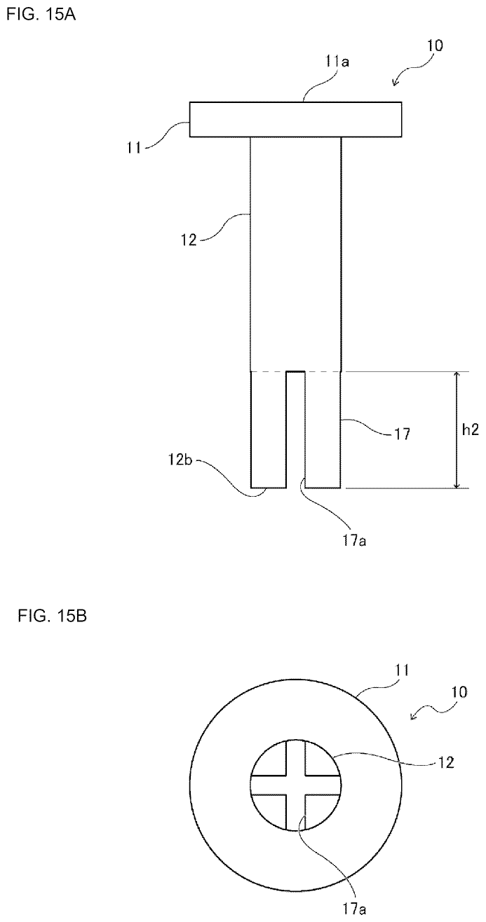

In a semiconductor device 101 of a fifth embodiment according to the present disclosure, as illustrated in FIG. 14, a solder suction band 16 having a slot 16a is formed in a region from a lower end 12b of a body portion 12 of a column 10 to a rising height h2 above a second solder 22. As illustrated in the bottom view of the column 10 in FIG. 14B, the slot 16a forms a slit passing through the axis of the body portion 12 in a region from the lower end 12b of the body portion 12 of the column 10 to the rising height h2 of the second solder 22.

The second solder 22 melted at an appropriate temperature by forming the slot 16a can cause solder wicking up to the rising height h2 of the second solder 22 along the slit of the slot 16a by surface tension.

Therefore, it is possible to reliably perform soldering up to the rising height h2 of the second solder 22. In addition, it is possible to perform control so that the rising height h2 of the second solder 22 does not vary.

Since the other configurations are similar to those of the first embodiment, the description thereof will be omitted.

### 7. Sixth Embodiment of Semiconductor Device According to the Present Disclosure

In a semiconductor device 101 of a sixth embodiment according to the present disclosure, as illustrated in FIG. 15, a solder suction band 17 having a cross groove 17a is formed in a region from a lower end 12b of a body portion 12 of a column 10 to a rising height h2 of a second solder 22. As illustrated in the bottom view of the column 10 in FIG. 15B, the cross groove 17a forms a cross slit passing through the axis of the body portion 12 in a region from the lower end 12b of the body portion 12 of the column 10 to the rising height h2 of the second solder 22.

By forming the cross groove 17a, the second solder 22 melted at an appropriate temperature can cause solder wicking up to the rising height h2 of the second solder 22 along the cross groove 17a due to surface tension.

Therefore, it is possible to reliably perform soldering up to the rising height h2 of the second solder 22. In addition, it is possible to perform control so that the rising height h2 of the second solder 22 does not vary.

Since the other configurations are similar to those of the first embodiment, the description thereof will be omitted.

Note that the regions including the solder suction bands 15, 16, and 17 of the columns 10 in the fourth to sixth embodiments and excluding the bending margin l may be subjected to the nickel gold (NiAu) plating described in the third embodiment.

### 8. Electronic Device Including Semiconductor Device or Mounting Substrate According to the Present Disclosure

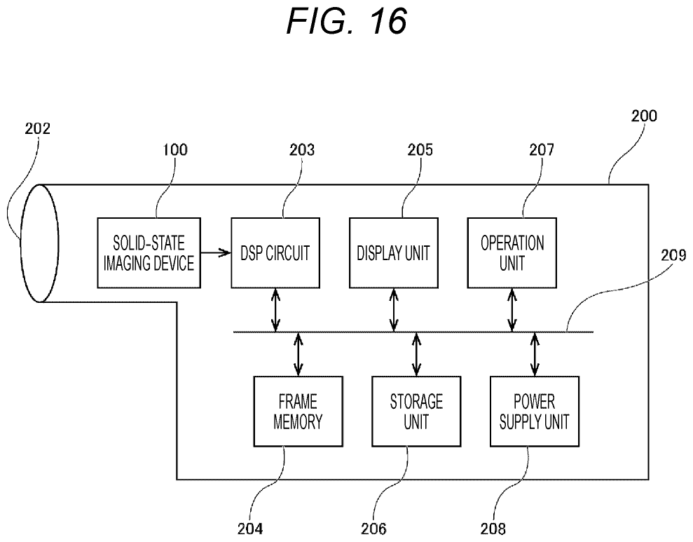

A configuration example of an electronic device including the solid-state imaging device 100 as an example of the semiconductor devices 101 according to the above first to sixth embodiments will be described with reference to FIG. 16.

The semiconductor device 101 according to the present disclosure can be applied to an imaging device such as a digital still camera, a video camera, and the like, a mobile terminal device having an imaging function, or an imaging device such as a copier using the solid-state imaging device 100 as an image reading unit. Furthermore, application thereof is not limited to the imaging device, and can be widely applied to a general electronic device such as an industrial apparatus including an electric home appliance, a communication apparatus, and an in-vehicle apparatus.

Note that the solid-state imaging device 100 may be a CMOS sensor or a CCD sensor. Furthermore, the solid-state imaging device 100 may be formed as one chip, or may be in the form of a module having an imaging function in which an imaging unit and a signal processing unit or an optical system are packaged together.

As illustrated in FIG. 16, an imaging apparatus 200 as an electronic device includes an optical unit 202, the solid-state imaging device 100, a digital signal processor (DSP) circuit 203 which is a camera signal processing circuit, a frame memory 204, a display unit 205, a recording unit 206, an operation unit 207, and a power supply unit 208. The DSP circuit 203, the frame memory 204, the display unit 205, the recording unit 206, the operation unit 207, and the power supply unit 208 are connected to one another through a bus line 209.

The optical unit 202 includes a plurality of lenses, and captures incident light (image light) from a subject to form an image on a pixel region (not illustrated) of the solid-state imaging device 100. The solid-state imaging device 100 converts a light amount of the incident light imaged on the pixel region thereof by the optical unit 202 into an electric signal in a pixel unit to output as a pixel signal.

The display unit 205 including a panel display device such as a liquid crystal panel and an organic electro luminescence (EL) panel, for example, displays a moving image or a still image captured by the solid-state imaging device 100. The recording unit 206 records the moving image or the still image captured by the solid-state imaging device 100 on a recording medium such as a hard disk or a semiconductor memory.

The operation unit 207 issues operation commands for various functions of the imaging device 200, in accordance with an operation by a user. The power supply unit 208 appropriately supplies various power sources serving as operation power sources of the DSP circuit 203, the frame memory 204, the display unit 205, the recording unit 206, and the operation unit 207 to these supply targets.

Furthermore, the semiconductor device 101 according to the present disclosure can be widely applied not only to the solid-state imaging device 100 but also to various semiconductor devices 101 constituting circuits such as the DSP circuit 203, the frame memory 204, the recording unit 206, the display unit 205, the operation unit 207, and the like.

As described above, according to the present disclosure, by using the solid-state imaging device 100 which is an example of the semiconductor device 101 according to the present disclosure or the mounting substrate 110 including the semiconductor device 101, it is possible to obtain the imaging device 200 having excellent reliability.

Finally, the description of each of the above-described embodiments is an example of the present disclosure, and the present disclosure is not limited to the above-described embodiments. For this reason, it is needless to say that various modifications other than each of the above embodiments can be made in accordance with the design and the like, without departing from the technical idea according to the present disclosure. Furthermore, the effects described in the present specification are merely examples and are not limited, and other effects may be provided.

Note that the present technology can also have the following configurations.

(1)

A semiconductor device including:
a semiconductor package having a plurality of lands on a lower surface;
a column having a flange portion at least at an upper end and joined to one of the lands; and
a first solder portion joining the land and the flange portion of the column, in which
the first solder portion has a melting point equivalent to a melting point of a second solder portion joining a lower end of the column to a land of a wiring board, and
the column is joined to the land of the semiconductor package via the first solder portion.
   (2)

The semiconductor device according to (1), in which the column has a second flange portion at a lower end.

(3)

The semiconductor device according to (1) or (2), in which the flange portion is covered with the first solder portion, and a portion having a pedestal thickness of the flange portion exists on a straight line connecting an upper end peripheral edge and a rising height h1 of the first solder portion.

(4)

The semiconductor device according to any one of (1) to (3), in which
each of the lands of the semiconductor package, the column having the flange portion at least at an upper end, the first solder portion, the second solder portion, and the land of the wiring board
satisfy a relationship of 3D/2≤R≤2D,
satisfy a relationship of 3d≤r≤4d, and
satisfy a relationship of L≥1+H, where
a diameter of the land of the semiconductor package is R,
a diameter of the flange portion at an upper end of the column is D,
a total length of the column is L,
a diameter of a body portion of the column is d,
a diameter of the land of the wiring board to which the lower end of the column is joined is r,
a rising height of the first solder portion from an upper end of the flange portion is h1,
a rising height of the second solder portion from a lower end of the body portion is h2, and
a bending margin of the column is l, and
H is a constant satisfying H=h1+h2.
   (5)

The semiconductor device according to any one of (1) to (3), in which
each of the lands of the semiconductor package, the column having the flange portion at an upper end and the second flange portion at a lower end, the first solder portion, the second solder portion, and the land of the wiring board
satisfy a relationship of 3D/2≤R≤2D,
satisfy a relationship of 3D_{L}/2≤r≤2D_{L}, and
satisfy a relationship of L≥1+H, where
a diameter of the land of the semiconductor package is R,
a diameter of the flange portion at an upper end of the column is D,
a diameter of the second flange portion at a lower end of the column is D_{L},
a total length of the column is L,
a diameter of the land of the wiring board to which the second flange portion at the lower end of the column is joined is r,
a rising height of the first solder portion from an upper end of the flange portion is h1,
a rising height of the second solder portion from a lower end of the body portion is h2, and
a bending margin of the column is l, and
H is a constant satisfying H=h1+h2.
   (6)

The semiconductor device according to (4) or (5), in which a value of the constant H is 0.48 when the column is plated with nickel gold (NiAu).

(7)

The semiconductor device according to any one of (1) to (6), in which in the column, a solder suction band is formed at least in a region of a rising height h2 of the second solder portion.

(8)

The semiconductor device according to (7), in which the solder suction band is formed by nickel gold (NiAu) plating.

(9)

The semiconductor device according to (7), in which the solder suction band has a plurality of grooves formed along an axial direction in a peripheral side surface of the column.

(10)

The semiconductor device according to (7), in which the solder suction band has a slot passing through an axis of the column.

(11)

The semiconductor device according to (7), in which the solder suction band has a cross groove passing through an axis of the column.

(12)

The semiconductor device according to any one of (1) to (11), in which the first solder portion and the second solder portion are low-temperature solders having equivalent melting points.

(13)

A mounting substrate including:
a semiconductor device including
a semiconductor package having a plurality of lands on a lower surface,
a column having a flange portion at least at an upper end and joined to one of the lands, and
a first solder portion joining the land and the flange portion of the column, in which
the first solder portion has a melting point equivalent to a melting point of a second solder portion joining a lower end of the column to a land of a wiring board, and
the column is joined to the land of the semiconductor package via the first solder portion, and the semiconductor device is joined to the land of the wiring board via the column and the second solder portion.
   (14)

An electronic device including:
a semiconductor device including
a semiconductor package having a plurality of lands on a lower surface,
a column having a flange portion at least at an upper end and joined to one of the lands, and
a first solder portion joining the land and the flange portion of the column, in which
the first solder portion has a melting point equivalent to a melting point of a second solder portion joining a lower end of the column to a land of a wiring board, and
the column is joined to the land of the semiconductor package via the first solder portion; or
a mounting substrate including a semiconductor device in which the column is joined to the land of the semiconductor package via the first solder portion is joined to the land of the wiring board via the column and the second solder portion.

### REFERENCE SIGNS LIST

10 Column
11 Flange portion
11L Second flange portion
11a Upper end (of flange portion)
12 Body portion
12b Lower end (of barrel portion)
14 Solder suction band
15 Solder suction band
15a Groove
16 Solder suction band
16a Slot
17 Solder suction band
17a Cross groove
21 First solder
21a Thickness (of solder)
21b Thickness (of solder)
22 Second solder
30 Semiconductor package
31 Land (of semiconductor package)
40 Wiring board
41 Land (of wiring board)
50 Suction head
51 Suction nozzle
52 Suction port
100 Solid-state imaging device
101 Semiconductor device
110 Mounting substrate
200 Imaging device
L Total length
1 Bending margin
h1 Lifting height of first solder
h2 Lifting height of second solder
D Diameter of flange portion
D_{L} Diameter of second flange portion
t Pedestal thickness
t1, t2 Thickness
d Diameter (of column or body portion)
R Diameter of land (of semiconductor package)
r Diameter of land (of wiring board)
H Constant
U, V, W, X Test sample
ϵ Bending amount

1. A semiconductor device comprising:
a semiconductor package having a plurality of lands on a lower surface;
a column having a flange portion at least at an upper end and joined to one of the lands; and
a first solder portion joining the land and the flange portion of the column, wherein
the first solder portion has a melting point equivalent to a melting point of a second solder portion joining a lower end of the column to a land of a wiring board, and
the column is joined to the land of the semiconductor package via the first solder portion.

2. The semiconductor device according to claim 1, wherein the column has a second flange portion at a lower end.

3. The semiconductor device according to claim 1, wherein the flange portion is covered with the first solder portion, and a portion having a pedestal thickness of the flange portion exists on a straight line connecting an upper end peripheral edge and a rising height h1 of the first solder portion.

4. The semiconductor device according to claim 1, wherein
each of the lands of the semiconductor package, the column having the flange portion at least at an upper end, the first solder portion, the second solder portion, and the land of the wiring board
satisfy a relationship of 3D/2≤R≤2D,
satisfy a relationship of 3d≤r≤4d, and
satisfy a relationship of L≥1+H, where
a diameter of the land of the semiconductor package is R,
a diameter of the flange portion at an upper end of the column is D,
a total length of the column is L,
a diameter of a body portion of the column is d,
a diameter of the land of the wiring board to which the lower end of the column is joined is r,
a rising height of the first solder portion from an upper end of the flange portion is h1,
a rising height of the second solder portion from a lower end of the body portion is h2, and
a bending margin of the column is l, and
H is a constant satisfying H=h1+h2.

5. The semiconductor device according to claim 1, wherein
each of the lands of the semiconductor package, the column having the flange portion at an upper end and the second flange portion at a lower end, the first solder portion, the second solder portion, and the land of the wiring board
satisfy a relationship of 3D/2≤R≤2D,
satisfy a relationship of 3D_{L}/2≤r≤2D_{L}, and
satisfy a relationship of L≥1+H, where
a diameter of the land of the semiconductor package is R,
a diameter of the flange portion at an upper end of the column is D,
a diameter of the second flange portion at a lower end of the column is D_{L}/a
total length of the column is L,
a diameter of the land of the wiring board to which the second flange portion at the lower end of the column is joined is r,
a rising height of the first solder portion from an upper end of the flange portion is h1,
a rising height of the second solder portion from a lower end of the body portion is h2, and
a bending margin of the column is l, and
H is a constant satisfying H=h1+h2.

6. The semiconductor device according to claim 4, wherein a value of the constant H is 0.48 when the column is plated with nickel gold (NiAu).

7. The semiconductor device according to claim 1, wherein in the column, a solder suction band is formed at least in a region of a rising height h2 of the second solder portion.

8. The semiconductor device according to claim 7, wherein the solder suction band is formed by nickel gold (NiAu) plating.

9. The semiconductor device according to claim 7, wherein the solder suction band has a plurality of grooves formed along an axial direction in a peripheral side surface of the column.

10. The semiconductor device according to claim 7, wherein the solder suction band has a slot passing through an axis of the column.

11. The semiconductor device according to claim 7, wherein the solder suction band has a cross groove passing through an axis of the column.

12. The semiconductor device according to claim 1, wherein the first solder portion and the second solder portion are low-temperature solders having equivalent melting points.

13. A mounting substrate comprising:
a semiconductor device including
a semiconductor package having a plurality of lands on a lower surface,
a column having a flange portion at least at an upper end and joined to one of the lands, and
a first solder portion joining the land and the flange portion of the column, wherein
the first solder portion has a melting point equivalent to a melting point of a second solder portion joining a lower end of the column to a land of a wiring board, and
the column is joined to the land of the semiconductor package via the first solder portion, and the semiconductor device is joined to the land of the wiring board via the column and the second solder portion.

14. An electronic device comprising:
a semiconductor device including
a semiconductor package having a plurality of lands on a lower surface,
a column having a flange portion at least at an upper end and joined to one of the lands, and
a first solder portion joining the land and the flange portion of the column, wherein
the first solder portion has a melting point equivalent to a melting point of a second solder portion joining a lower end of the column to a land of a wiring board, and
the column is joined to the land of the semiconductor package via the first solder portion; or
a mounting substrate including a semiconductor device in which the column is joined to the land of the semiconductor package via the first solder portion is joined to the land of the wiring board via the column and the second solder portion.
